(19) United States
(12) Patent Application Publication
(10) Pub. No.: US 2006/0017057 A1
(43) Pub. Date: Jan. 26, 2006

(54) Device structure to improve OLED reliability

(76) Inventors: Brian H. Cumpston, Pleasanton, CA (US); Pierre-Marc Allemand, San Jose, CA (US); Vi-En Choong, San Jose, CA (US); Rahul Gupta, Milpitas, CA (US)

Correspondence Address: Siemens Corporation;Attn: Elsa Keller, Legal Administrator, Intellectual Property Department, 170 Wood Avenue South, Iselin, NJ, 08830, US

(21) Appl. No.: 10/895,862

(22) Filed: Jul. 20, 2004

(51) Int. Cl. H01L 29/22; H01L 29/227; H01L 33/00; B32B 9/00; B32B 19/00

(52) U.S. Cl. 257/98

(57) ABSTRACT

An organic light emitting diode (“OLED”) device is formed with a thick light emitting polymer layer, hole transporting layer and an interlayer between the thick LEP layer and the hole transporting layer.

### CROSS-REFERENCE TO RELATED APPLICATIONS

This application is a continuation-in-part of a pending U.S. patent application entitled “Thick Light Emitting Polymers to Enhance OLED Efficiency and Lifetime” filed on Jun. 15, 2004, bearing attorney docket number 2004P04185US01, which claims priority from a provisional application entitled “Thick Light Emitting Polymers to Enhance OLED Efficiency and Lifetime,” filed on Mar. 30, 2004, bearing attorney docket number 2004P04185US, assigned Ser. No. 60/557,464.

### BACKGROUND

An organic light emitting diode (“OLED”) display is typically comprised of: (1) a transparent anode (e.g. ITO (Indium Tin Oxide) on a substrate; (2) a hole transporting layer (“HTL”); (3) an electron transporting and light emitting layer (“emissive layer” or “LEP layer” (light emitting polymer layer)); and (4) a cathode. When a forward bias is applied, holes are injected from the anode into the HTL, and the electrons are injected from the cathode into the emissive layer. Both carriers are then transported towards the opposite electrode and allowed to recombine with each other, the location of which is called the recombination zone. The recombination of holes and electrons in the emissive layer produce excitons which then emit light.

The emissive layer in an OLED typically is composed of one or more organic compounds (such as monomers or polymers) dissolved in a solvent. The organic solution may contain other elements such as wetting agents, cross-linking agents, side-groups and so on. The emissive layer is fabricated by depositing this organic solution onto the HTL or other underlying layer and allowing or causing (by baking or cross-linking) the solution to dry into a film. The organic solution may be deposited using selective deposition techniques such as inkjet printing or non-selective deposition techniques such as spin-coating.

The injection of charge carriers into conjugated polymers is usually optimized by the matching of the work function of the electrode to the energy level into which the charges are to be injected. This limits the choice of electrodes that can be used with a given polymer, especially for the anode where the choice of electrodes are more limited. Because of the large barrier to hole injection from ITO, a typical transparent anode, a hole injection and transport layer (the HTL) is typically used to bridge the barrier and enhance injection. However, work in the literature has indicated that the reliability of the OLED device may be adversely affected by the use of these hole transport layers. This may be caused by the leaching out of constituents from the hole transport layer into the LEP that degrades the performance of the device during operation.

There are different reasons put forth for where these constituents come from, and under what conditions they are formed. One of which is that the HTL is not very stable in the presence of energetic electrons, and electrons injected into the HTL from the LEP will degrade the HTL. Thus, the more energetic electrons that get transferred into the HTL, and cause degradation, the lower the lifetime of the device. Thus, in this scenario, LEPs that are electron dominant will have very bad lifetime as the recombination will be at the HTL/LEP interface, and a lot of energetic electrons will be leaking into the HTL. It has been shown that having a thinner HTL can improve the reliability of the device, presumably by reducing the reservoir of these bad components, and also increasing the amount of holes injected into the device thus effectively reducing the amount of energetic electrons that get injected into the HTL. Another method is to put an interlayer between the HTL and LEP which either acts as an electron blocker, or has transport properties such that hole transport is much better than electron transport, which tilts the electron/hole ratio in favor of holes, and physically removes the recombination zone from the HTL/LEP interface.

As shown in FIG. 2, adding an interlayer modifies the lifetime decay curve to exhibit a leveling off behavior which is desirable in order to lengthen device reliability in addition to lowering the increase in operating voltage. The device with an interlayer is marked by triangular-shaped markers and the device without the interlayer is marked by X-shaped markers. This approach improves device reliability, but at a cost of higher operating voltages and a more complicated fabrication process. Another method is to increase the thickness of the LEP, which effectively tilts the hole/electron ratio in favor of holes. This has also been shown to increase lifetime as discussed in the parent patent application and shown in FIG. 1. As shown in FIG. 1, devices with a thicker LEP layer (A>B>C) show improved performance over a longer lifetime but also suffer from operating voltages (A>B>C). This approach bears the cost of higher operating voltages and that the change in operating voltage as a function of time is also very high. Also, the lifetime increase is predominantly due to the reduction of the initial luminance decay, while the main decay slope remains the same. The magnitude of this reduction scales with the thickness of the LEP. In addition, the luminance decay curve does not level off. This limits the amount of improvement that can be achieved with this method as there is a limit to where the increase of LEP thickness becomes impractical.

Therefore, there is a need to improve OLED device efficiency and lifetime without these tradeoffs while still improving device reliability.

### BRIEF DESCRIPTION OF THE DRAWINGS

FIG. 1 illustrates device luminance and voltage at various LEP layer thickness for a set of OLED devices.

FIG. 2 illustrates device luminance and voltage at various for a set of OLED devices with and without an interlayer.

FIG. 3 illustrates device luminance and voltage for a set of OLED devices which combine thick LEP layers with interlayers.

FIG. 4 shows a cross-sectional view of an embodiment of an organic electronic device 405 according to at least one embodiment of the invention.

FIG. 5 illustrates the effects of thinner HTL layers in accordance with at least one embodiment of the invention.

### DETAILED DESCRIPTION

In at least one embodiment of the invention, an OLED device structure is disclosed which combines the use of a “thick” light emitting polymer (LEP) layer and an interlayer between the LEP layer and HTL layer. OLEDs utilizing thick LEP layers have been illustrated and described in the parent patent application. An increase in LEP thickness and added interlayer is typically associated with a great increase in required drive voltage. This might be expected to decrease efficiency and lifetime because of the additional stress on the device. Higher operating voltages also imposes greater requirements on drivers needed to power the OLEDs, and increases power consumption of the OLEDs, reducing its attactiveness for use in portable devices. To avoid this anticipated decrease in performance, and for the reason that many low voltage applications require thin LEP layers rather than thick LEP layers, it is atypical to use a thick LEP layer. However, as discussed above and demonstrated below, the thick LEP layer combined with an interlayer actually and unexpectedly increases efficiency and lifetime.

In other embodiments of the invention, the thick LEP layer and interlayer are combined with a thinner HTL layer. OLED devices with a constant combined total LEP layer and HTL layer thickness is disclosed in the parent patent application. However, in those cases, the decrease in HTL layer thickness is due to the needed increase in LEP layer thickness. The addition of an interlayer between the HTL and LEP layer may add to the total device thickness, thereby presumably increasing operating voltages and decreasing device lifetime, but this has experimentally been shown to be false.

A typical conventional OLED device with only an HTL and LEP layers may show an HTL of about 60 nm and LEP of 75 nm thickness. In at least one exemplary embodiment of the invention, an interlayer would be added and the LEP layer would be made thicker. An example of such a device structure would include an HTL of 60 nm followed by an interlayer of 30 nm and an LEP layer of 125 nm thickness.

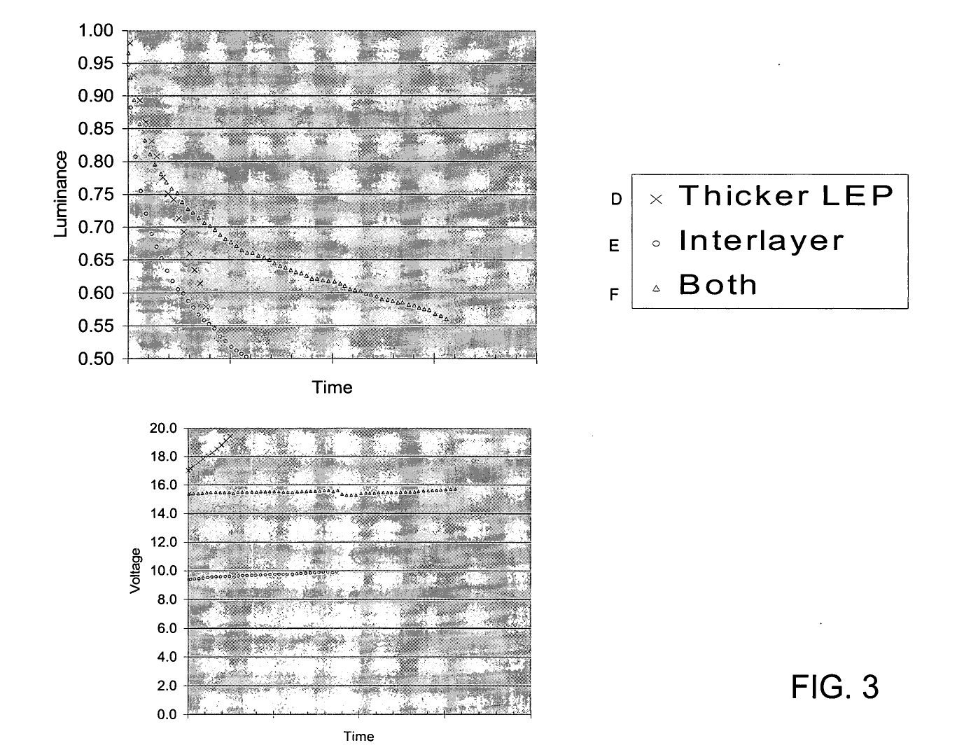

Ordinary analysis of such a device structure would indicate that this structure would not be desirable as a bi-layer device with thicker LEP already has a high operating voltage-adding another layer to that device structure would just further increase the operating voltage. Contrary to what may be expected, the initial operating voltage of such a device is even lower than a device with similar LEP thickness and no interlayer. Furthermore, as shown in FIG. 3, the luminance decay curve retains the leveling off behavior commonly associated with devices having an interlayer, which are necessary to have large improvements in device reliability. This structure also retains the reduction of the initial luminance decay observed for thicker LEP devices. Furthermore, the structure retains the low dV/dt (change in device operating voltage as a function of time) commonly associated with devices having an interlayer.

As mentioned above, in still other embodiments of the invention, a thicker LEP layer and interlayer would be combined with a thinner-than-typical HTL layer. One such device may have an HTL of only 30 nm as opposed to 60 nm, and a thick LEP layer 125 nm along with an interlayer disposed between the LEP layer and thin HTL. The characteristics and performance of such devices is illustrated and discussed below.

FIG. 3 illustrates the effects of utilizing a thick LEP layer in conjunction with an interlayer in an OLED device in accordance with at least one embodiment of the invention. The first curve marked by X-shaped markers, is of an OLED device which has a thick LEP layer but no interlayer (D). The second curve marked by circle markers, is of an OLED device which has an interlayer but no thick LEP layer (E). The third curve, marked by triangular markers, is of an OLED device which, in accordance with at least one embodiment of the invention, has both a thick LEP layer and interlayer (F).

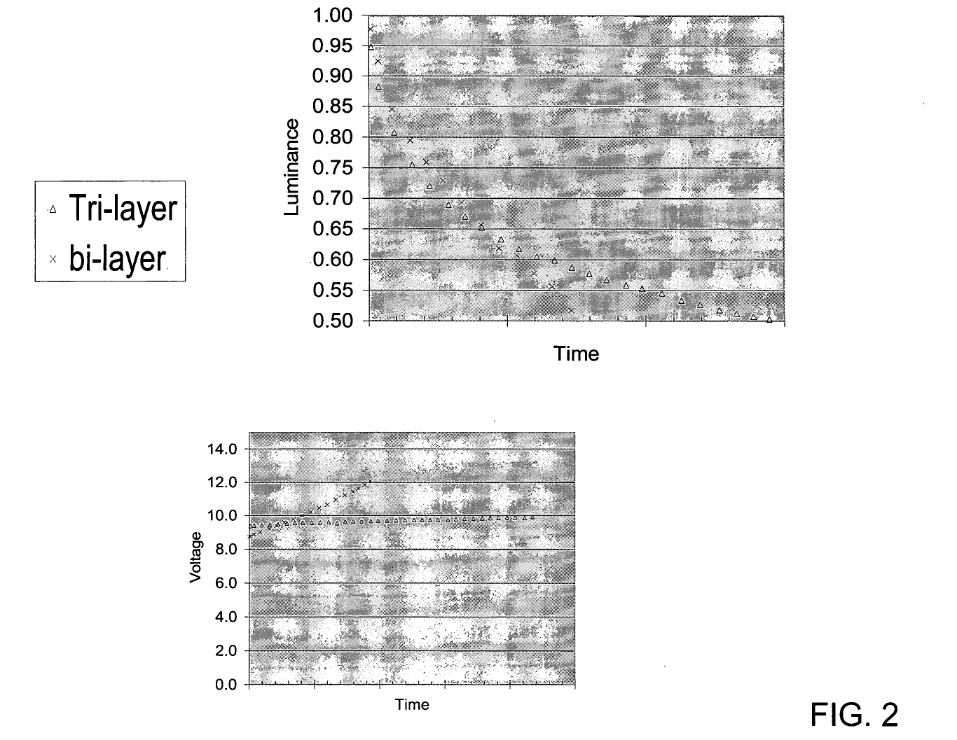

Device F shows the best improvement in lifetime retaining more of initial luminance as lifetime increases. Device D with only a thick LEP layer has the advantage of less of an initial drop in luminance but a rapid rate of declining luminance at longer lifetimes. Most unexpectedly, the voltage required to drive device F is less than the voltage required to drive device D, even though the thickness of the organic layers in device F is greater (due to the presence of the interlayer). It is postulated that even though the total thickness is kept the same, the amount of voltage drop across each layer is different. Typically, the LEP drops a lot more voltage than the HTL. For instance, increasing the LEP thickness by 30 nm, and reducing the HTL thickness by 30 nm, might provide the same overall device thickness, but the operating voltage of that device may be higher. Device E requires the lowest operating voltage but also has the greatest drop in initial luminance amongst the three devices. However, as shown in FIG. 2, the operating voltage of Device E is higher than that of a corresponding bi-layer device with the same LEP thickness as expected. Even with the higher operating voltages, the lifetime of Device E is higher.

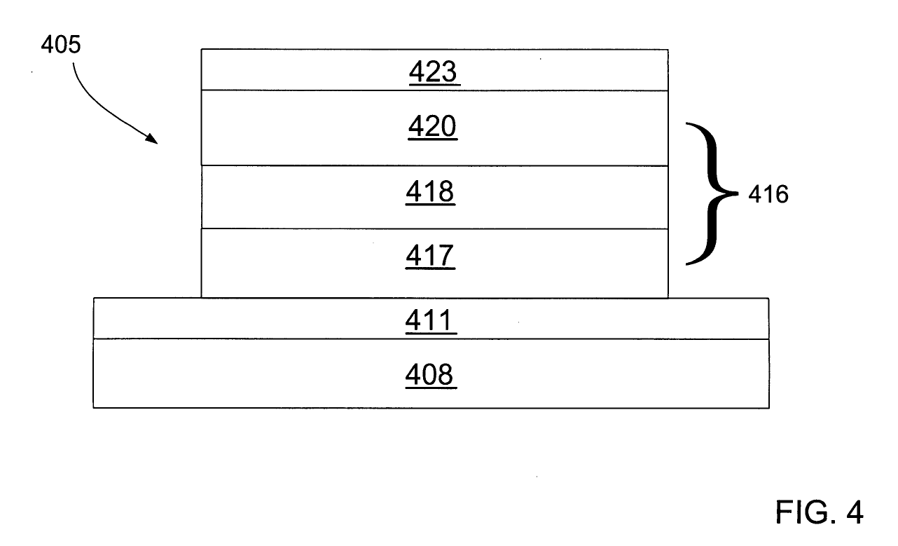

FIG. 4 shows a cross-sectional view of an embodiment of an OLED device 405 according to at least one embodiment of the invention. The OLED device 405 may represent one OLED pixel or sub-pixel of a larger OLED display. As shown in FIG. 4, the OLED device 405 includes a first electrode 411 on a substrate 408. As used within the specification and the claims, the term “on” includes when layers are in physical contact or when layers are separated by one or more intervening layers. The first electrode 411 may be patterned for pixilated applications or unpatterned for backlight applications.

One or more organic materials is deposited into the aperture to form one or more organic layers of an organic stack 416. The organic stack 416 is on the first electrode 411. The organic stack 416 includes a hole transporting (conducting polymer) layer (“HTL”) 417 and light emitting polymer (LEP) layer 420 and an interlayer 418 disposed between the HTL 417 and the LEP layer 420. If the first electrode 411 is an anode, then the HTL 417 is on the first electrode 411. Alternatively, if the first electrode 411 is a cathode, then the active electronic layer 420 is on the first electrode 411, and the HTL 417 is on the LEP layer 420. The OLED device 405 also includes a second electrode 423 on the organic stack 416. Other layers than that shown in FIG. 4 may also be added including barrier, charge transport, and interface layers between or among any of the existing layers as desired. Some of these layers, in accordance with the invention, are described in greater detail below. The “thickness” of a given layer is the distance or extension of that layer in a vertical direction of the shown cross-section as measured between the bottom of the layer immediately above the given layer and the top of the layer immediately below the given layer.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. The substrate can also have transistors or other switching elements built in to control the operation of an active-matrix OLED device. A single substrate 408 is typically used to construct a larger OLED display containing many pixels (OLED devices) such as OLED device 405 arranged in some pattern.

First Electrode 411:

In one configuration, the first electrode 411 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO (Indium Tin Oxide), and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device. The thickness of the first electrode 411 can be from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

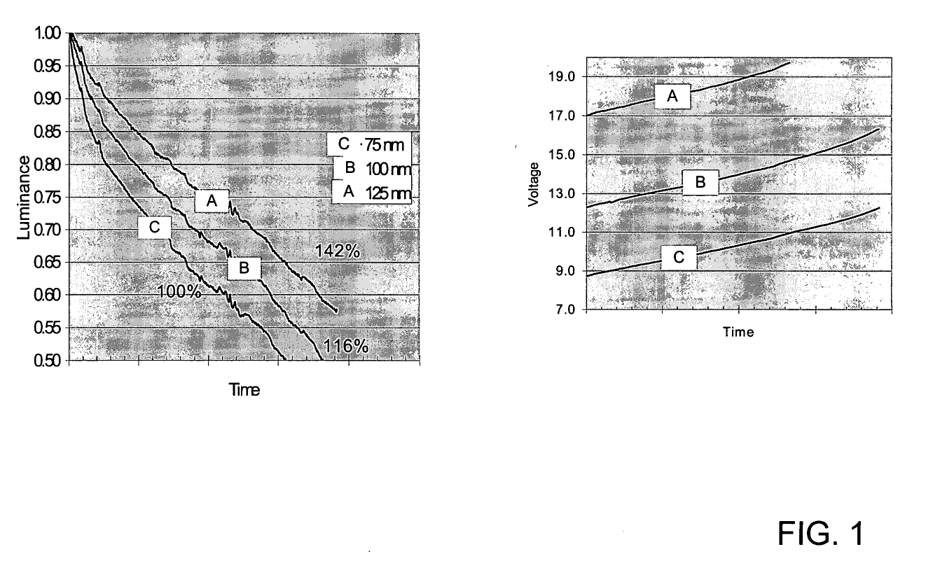

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are listed below in the section for the “second electrode 423”. In the configuration used in obtaining the experimental results shown in FIGS. 1-3 and 5, the first electrode 411 was an anode comprised of ITO.

HTL 417:

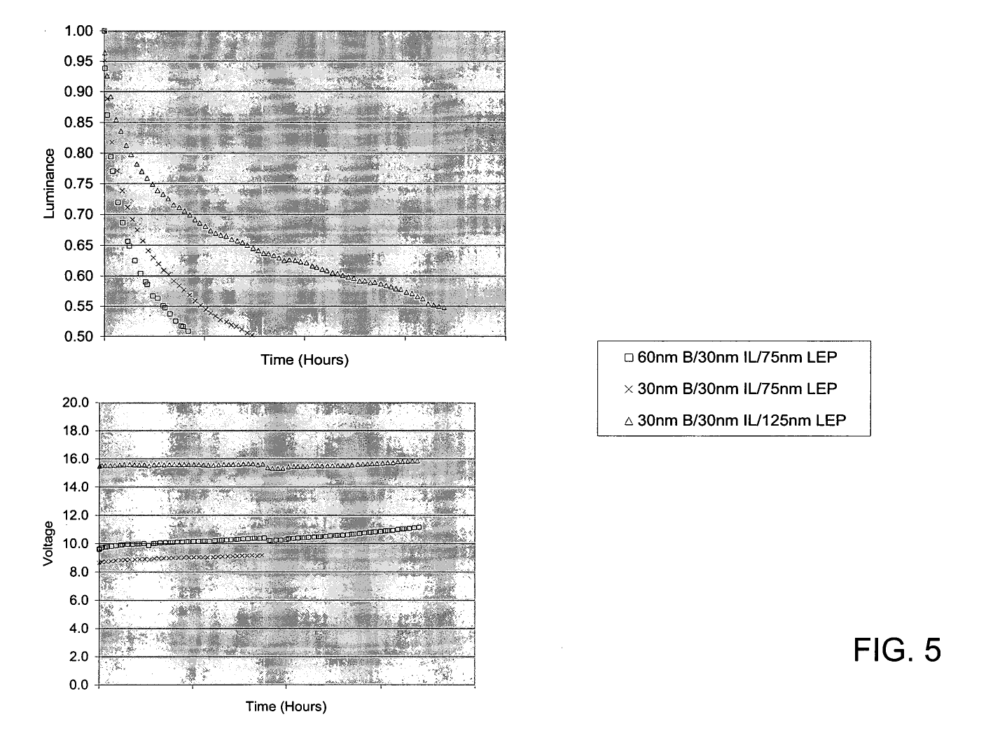

The HTL 417 has a much higher hole mobility than electron mobility and is used to effectively transport holes from the first electrode 411 to the substantially uniform organic polymer layer 420. The HTL 417 is made of polymers or small molecule materials. For example, the HTL 417 can be made of tertiary amine or carbazole derivatives both in their small molecule or their polymer form, conducting polyaniline (“PANI”), or PEDOT:PSS (a solution of polyethylenedioxythiophene (“PEDOT”) and polystyrenesulfonic acid (“PSS”) available as Baytron P from HC Starck). The HTL 417 can have a thickness from about 5 nm to about 1000 nm, and is conventionally used from about 50 to about 250 nm. In one or more embodiments of the invention, a thin HTL is also disclosed. A “thin” HTL would have a thickness of around 30 nm and can be combined with a thick LEP layer 420 and interlayer 418. The effects of a thin HTL with and without these additional device features is illustrated in FIG. 5.

The HTL 417 can be formed using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. The hole transporting material is deposited on the first electrode 411 and then allowed to dry into a film. The dried material represents the hole transport layer.

Interlayer 418:

In accordance with at least one embodiment of the invention, a thick LEP layer is utilized in a device structure also having an interlayer between the LEP layer and the HTL layer. In this exemplary embodiment, an interlayer 418 is provided between HTL 417 and LEP layer 420.

The functions of the interlayer 418 are among the following: to help injection of holes into the LEP layer 420, reduce exciton quenching at the anode, possess better hole transport than electron transport, and block electrons from getting into the HTL 417 and degrading it. Some materials may have one or two of the desired properties listed, but the effectiveness of the material as an interlayer is believed to improve with the number of these properties exhibited. Through careful selection of the materials, an efficient interlayer material can be found. Examples of criteria that can be used are as follows: a criteria that can be used to find materials that can help injection of holes into the LEP layer 420 is that the HOMO (Highest Occupied Molecular Orbital) levels of the material bridge the energy barrier between the anode and the LEP layer 420, that is the HOMO level of the interlayer 418 should be in between the HOMO levels of the anode and the LEP layer 420. Charge carrier mobilities of the materials can be used as a criteria to distinguish materials that will have better hole transport than electron transport. Also, materials that have higher LUMO (Lowest Unoccupied Molecular Orbital) levels than the LUMO of the LEP layer 420 will present a barrier to electron injection from the LEP layer 420 into the interlayer 418, and thus act as an electron blocker. The interlayer 418 may consist at least partially of or may derive from one or more following compounds, their derivatives, moieties, etc: poly(2,7-(9,9-di-n-octylfluorene)-(1,4-phenylene-((4-secbutylphenyl)imino)-1,4-phenylene) and derivatives which include cross-linkable forms, non-emitting forms of poly(p-phenylenevinylene), triarylamine type material, thiopene, etc.

The interlayer can have a thickness of anywhere between about 5 nm and 100 nm and preferably, has a thickness from about 10 nm to 30 m.

LEP Layer 420:

For organic LEDs (OLEDs), the LEP layer 420 contains at least one organic material that emits light. These organic light emitting materials generally fall into two categories. The first category of OLEDs, referred to as polymeric light emitting diodes, or PLEDs, utilize polymers as part of LEP layer 420. The polymers may be organic or organo-metallic in nature. As used herein, the term organic also includes organo-metallic materials. Preferably, these polymers are solvated in an organic solvent, such as toluene or xylene, and spun (spin-coated) onto the device, although other deposition methods are possible. Devices utilizing polymeric active electronic materials in LEP layer 420 are especially preferred. Optionally, LEP layer 420 may include a light responsive material that changes its electrical properties in response to the absorption of light. Light responsive materials are often used in detectors and solar panels that convert light energy to electrical energy.

The light emitting organic polymers in the LEP layer 420 can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, the organic polymers can be, for example: polyfluorenes; poly-p-phenylenevinylenes that emit white, red, blue, yellow, or green light and are 2-, or 2, 5-substituted poly-p-pheneylenevinylenes; polyspiro polymers. Preferred organic emissive polymers include LUMATION Light Emitting Polymers (“LEPs”) that emit green, red, blue, or white light or their families, copolymers, derivatives, or mixtures thereof; the LUMATION LEPs are available from The Dow Chemical Company, Midland, Mich. Other polymers include polyspirofluorene-like polymers available from Covion Organic Semiconductors GmbH, Frankfurt, Germany.

In addition to polymers, smaller organic molecules that emit by fluorescence or by phosphorescence can serve as a light emitting material residing in LEP layer 420. Unlike polymeric materials that are applied as solutions or suspensions, small-molecule light emitting materials are preferably deposited through evaporative, sublimation, or organic vapor phase deposition methods. Combinations of PLED materials and smaller organic molecules can also serve as active electronic layer. For example, a PLED may be chemically derivatized with a small organic molecule or simply mixed with a small organic molecule to form LEP layer 420.

In addition to active electronic materials that emit light, LEP layer 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, compositions including C60, and compositions including derivatized C60 may be used. LEP layer 420 may also include semiconductors, such as silicon or gallium arsenide.

In accordance with at least one embodiment of the invention, the LEP layer 420 has a thickness of greater than 80 nm and preferably, between 80 and 200 nm. “Thickness of the LEP layer” as used in describing this and other embodiments of the invention, refers to the distance between bottom of the second electrode 423 and the top of the HTL 417 in a vertical direction. The thicker LEP layer 420 has been shown to increase the photopic efficiency and lifetime of device 420. In other embodiments of the invention, the combined thickness of the layers in the organic stack, i.e. LEP layer 420, interlayer 418 and HTL 417, is held at a constant such that the individual layer thicknesses could be optimized without an undue increase in overall thickness.

All of the organic layers such as HTL 417, interlayer 418 and LEP layer 420 can be ink-jet printed by depositing an organic solution or by spin-coating, or other deposition techniques. This organic solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops.

The LEP layer 420 is fabricated by depositing this solution, using either a selective or non-selective deposition technique, onto HTL 417. To obtain a thicker LEP layer 420, in accordance with the invention, more drops or a greater concentration of polymer solution or a slower rotational speed while spin coating is required to be deposited. Further, each of the layers 417, 418 and 420 may be cross-linked or otherwise physically or chemically hardened as desired for stability and maintenance of certain surface properties desirable for deposition of subsequent layers.

Second Electrode (423)

In one embodiment, second electrode 423 functions as a cathode when an electric potential is applied across the first electrode 411 and second electrode 423. In this embodiment, when an electric potential is applied across the first electrode 411, which serves as the anode, and second electrode 423, which serves as the cathode, photons are released from active electronic layer 420 that pass through first electrode 411 and substrate 408.

While many materials, which can function as a cathode, are known to those of skill in the art, most preferably a composition that includes aluminum, indium, silver, gold, magnesium, calcium, and barium, or combinations thereof, or alloys thereof, is utilized. Aluminum, aluminum alloys, and combinations of magnesium and silver or their alloys can also be utilized.

Preferably, the thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred. Other layers (not shown) such as a barrier layer and getter layer may also be used to protect the electronic device. Such layers are well-known in the art and are not specifically discussed herein.

Often other steps such as washing and neutralization of films, the addition of masks and photo-resists may precede the cathode deposition. However, these are not specifically enumerated as they do not relate specifically to the novel aspects of the invention. Other steps (not shown) like adding metal lines to connect the anode lines to power sources may also be included in the workflow. Also, for instance, after the OLED is fabricated it is often encapsulated to protect the layers from environmental damage or exposure. Such other processing steps are well-known in the art and are not a subject of the invention.

FIG. 5 illustrates the effects of a thin HTL layer in various device structures in accordance with at least one embodiment of the invention. The three curves of FIG. 5 illustrate results of measurements taken on three different devices. The first device (I) had a conventional thickness HTL along with interlayer and conventional thickness LEP layer. The second device (II) had a thin HTL along with an interlayer and conventional thickness LEP layer. The third device (III) had a thin HTL, interlayer and a thick LEP layer. Device III showed an over 400% improvement (over device I) in lifetime at half of initial luminance. Device II shows a 155% improvement (over device I) in lifetime at half initial luminance.

While the embodiments of a thicker LEP layer and interlayer combination are illustrated in which it is incorporated within an OLED device, this concept may be applied to other electronic devices that use an active electronic layer. For example, with a solar cell, the light responsive layer (i.e., the active electronic layer) can be comprised of a thick film polymer. The OLED device described earlier can be used in applications such as, for example, computer displays, information displays in vehicles, television monitors, telephones, printers, and illuminated signs, general lighting, night lights, and backlights.

As any person of ordinary skill in the art of electronic device fabrication will recognize from the description, figures, and examples that modifications and changes can be made to the embodiments of the invention without departing from the scope of the invention defined by the following claims.

What is claimed:

1. An organic light emitting diode (“OLED”) device having a plurality of stacked layers, comprising:
a hole transporting layer;
a light emitting polymer layer having a thickness, as measured between two layers adjacent thereto of between eighty and two hundred nanometers; and
an interlayer disposed between said hole transporting layer and said light emitting polymer layer, said interlayer functioning to provide at least one of:
a) aiding the injection of holes into said light emitting polymer layer;
b) blocking of electrons from migrating to said hole transporting layer; and
c) reducing of exciton quenching.

2. A device according to claim 1 further comprising:
an anode layer, said anode layer adjacent to said light emitting polymer layer.

3. A device according to claim 2 further comprising:
a cathode layer.

4. A device according to claim 2 wherein said hole transporting layer and said light emitting polymer layer are formed using at least one organic material.

5. A device according to claim 4 wherein said light emitting polymer layer is formed using at least one of a selective deposition technique and a non-selective deposition technique.

6. A device according to claim 5 wherein said selective deposition technique includes inkjet printing.

7. A device according to claim 5 wherein said non-selective deposition technique includes spin coating.

8. A device according to claim 1 wherein said device is used to create an OLED display.

9. A device according to claim 8 wherein said OLED display is passive matrix in nature.

10. A device according to claim 2 wherein the combined thickness of the light emitting polymer layer and hole transporting layer is held fixed, the thickness of the hole transporting layer decreasing with an increase in the thickness of the light emitting polymer layer.

11. A device according to claim 8 wherein said OLED display is active matrix in nature.

12. An organic light emitting diode (“OLED”) device having a plurality of stacked layers, comprising:
a hole transporting layer;
a light emitting polymer layer having a thickness, as measured between two layers adjacent thereto of more than eighty nanometers; and
an interlayer disposed between said hole transporting layer and said light emitting polymer layer, said interlayer functioning to provide at least one of:
a) aiding the injection of holes into said light emitting polymer layer;
b) blocking of electrons from migrating to said hole transporting layer; and
c) reducing of exciton quenching.

13. A device according to claim 12 further comprising:
an anode layer, said anode layer adjacent to said light emitting polymer layer.

14. A device according to claim 13 further comprising:
a cathode layer.

15. A device according to claim 13 wherein said hole transporting layer and said light emitting polymer layer are formed using at least one organic material.

16. A device according to claim 15 wherein said light emitting polymer layer is formed using at least one of a selective deposition technique and a non-selective deposition technique.

17. A device according to claim 16 wherein said selective deposition technique includes inkjet printing.

18. A device according to claim 16 wherein said non-selective deposition technique includes spin coating.

19. A device according to claim 12 wherein said device is used to create an OLED display.

20. A device according to claim 19 wherein said OLED display is passive matrix in nature.

21. A device according to claim 13 wherein the combined thickness of the light emitting polymer layer and hole transporting layer is held fixed, the thickness of the hole transporting layer decreasing with an increase in the thickness of the light emitting polymer layer.

22. A device according to claim 19 wherein said OLED display is active matrix in nature.

23. A device according to claim 1 wherein said hole transporting layer has a thickness of about 30 nanometers.

24. A device according to claim 12 wherein said hole transporting layer has a thickness of about 30 nanometers.

25. A device according to claim 1 wherein said interlayer is formed using at least one of: poly(2,7-(9,9-di-n-octylfluorene)-(1,4-phenylene-((4-secbutylphenyl)imino)-1,4-phenylene), non-emitting forms of poly(p-phenylenevinylene), triarylamine type material and thiopene.

26. A device according to claim 12 wherein said interlayer is formed using at least one of: poly(2,7-(9,9-di-n-octylfluorene)-(1,4-phenylene-((4-secbutylphenyl)imino)-1,4-phenylene), non-emitting forms of poly(p-phenylenevinylene), triarylamine type material and thiopene.

27. A device according to claim 1 wherein said interlayer has a thickness from about 5 nanometers to about 100 nanometers.

28. A device according to claim 1 wherein said interlayer has a thickness from about 10 nanometers to about 30 nanometers.

29. A device according to claim 1 wherein said interlayer has a thickness from about 5 nanometers to about 100 nanometers.

30. A device according to claim 1 wherein said interlayer has a thickness from about 10 nanometers to about 30 nanometers.
